(19) United States
(12) Patent Application Publication
(10) Pub. No.: US 2016/0054825 A1
(43) Pub. Date: Feb. 25, 2016

(54) TOUCH PANELS AND METHODS

(71) Applicant: Carestream Health, Inc., Rochester, NY (US)

(72) Inventor: Andrew T. Fried, Woodbury, MN (US)

(21) Appl. No.: 14/806,919

(22) Filed: Jul. 23, 2015

Related U.S. Application Data
(60) Provisional application No. 62/041,335, filed on Aug. 25, 2014.

(51) Int. Cl. G06F 3/041; H05K 1/02

(52) U.S. Cl. CPC G06F 3/041; G06F 3/0414; H05K 1/028; G06F 2203/04103; G06F 2203/04104

(57) ABSTRACT

A touch panel including a polymer substrate exhibiting a heat deflection temperature at which the polymer substrate becomes substantially deformable, a transparent conductive film disposed on the polymer substrate, the transparent conductive film including a body portion, a tail portion integrally formed with the body portion, and a plurality of conductive structures at least some of which are embedded within the body portion and tail portion, an electronic assembly compound disposed between the transparent conductive film and at least one electronic component, the electronic assembly compound exhibiting a curing temperature range that is less than 185° C., at least a portion of the curing temperature range being colder than the heat deflection temperature, where the at least one electronic component is bonded to the transparent conductive film by the electronic assembly compound.

### CROSS REFERENCE TO RELATED APPLICATIONS

This application claims the benefit of U.S. Provisional Application No. 62/041,335, filed Aug. 25, 2014, entitled “TOUCH PANELS,” which is hereby incorporated by reference in its entirety.

### BACKGROUND

Touch panel devices employ an electronic visual display that the user can control through simple or multi-touch gestures. Touch panel devices include game consoles, all-in-one computers, tablet computers, and smartphones. A touch panel configuration may include a flexible printed circuit (FPC) providing connections between the touch panel sensor and the printed circuit board (PCB). On a touch panel sensor, the FPC may be characterized as a “tail” extending from the touch panel sensor. In some cases, the FPC may be a component that is separately formed from the touch panel sensor and later attached to the touch panel sensor. In other cases, an electrical component that has structural (e.g. “tail” shape) or functional (e.g. providing electrical connections) similarities to the FPC may be formed integrally with the touch panel sensor.

Touch panels may have a variety of configurations that may be produced through various fabrication methods using various materials. See, for example, U.S. Pat. No. 4,484,038 to Dorman et al., U.S. Pat. No. 4,085,302 to Zenk et al., U.S. Pat. No. 6,819,316 to Schulz et al., U.S. Patent Application Publication No. 2012/0200506 to Taylor et al., U.S. Pat. No. 6,587,097 to Aufderheide et al., U.S. Pat. No. 7,439,962 to Reynolds et al., and U.S. Pat. No. 8,330,742 to Reynolds et al.

### SUMMARY

In some embodiments, a touch panel is disclosed as comprising a polymer substrate exhibiting a heat deflection temperature at which the polymer substrate becomes substantially deformable, a transparent conductive film disposed on the polymer substrate, the transparent conductive film comprising a body portion, a tail portion integrally formed with the body portion, and a plurality of conductive structures embedded within the body portion and the tail portion, an electronic assembly compound disposed between the transparent conductive film and at least one electronic component, the electronic assembly compound exhibiting a curing temperature range that is less than 185° C., at least a portion of the curing temperature range being colder than the heat deflection temperature, where the at least one electronic component is bonded to the transparent conductive film by the electronic assembly compound.

In some embodiments, the body portion comprises a first composition, and the tail portion comprises a second composition, the first composition and the second composition being the same.

In some embodiments, the entirety of the curing temperature range is less than about 180 degrees Celsius. In some embodiments, the curing temperature range is less than about 180 degrees Celsius. In some embodiments, the curing temperature range is between about 135 degrees Celsius and about 155 degrees Celsius. In some embodiments, the curing temperature range is between about 140 degrees Celsius and about 150 degrees Celsius. In some embodiments, the curing temperature range is less than about 150 degrees Celsius. In some embodiments, the curing temperature range is less than about 140 degrees Celsius.

In some embodiments, the electronic assembly compound comprises a silver epoxy. In some embodiments, the polymer substrate comprises polyethylene terephthalate. In some embodiments, the plurality of conductive structures comprises silver nanowires. In some embodiments, a silver ink is disposed onto the transparent conductive film, such that the silver ink is interposed between the transparent conductive film and the electronic assembly compound. In some embodiments, a silver ink and a carbon ink is disposed onto the transparent conductive film, such that the silver ink is interposed between the transparent conductive film and the carbon ink and the carbon ink is interposed between the silver ink and the electronic assembly compound. In some embodiments, the transparent conductive film comprises a patterned region exhibiting a first conductivity and an unpatterned region exhibiting a second conductivity, the first conductivity being less than the second conductivity.

In at least some of embodiments, the transparent conductive film is a one-piece transparent conductive film.

In some embodiments, a dielectric compound curable by ultraviolet radiation is disposed on the tail portion. In some embodiments, at least one electronic component is disposed on the electronic assembly compound. In some embodiments, an optical clear adhesive is disposed on the transparent conductive film. In some embodiments, a cover lens is disposed on the optical clear adhesive. In some embodiments, the electronic assembly compound is disposed on the tail portion. In some embodiments, the electronic assembly compound is disposed on the tail portion, at least one electronic component is disposed on the electronic assembly compound, and at least one stiffener is disposed under the at least one electronic component. In some embodiments, the tail portion comprises a first end connected with the body portion and a second end configured for connection with a connector, the second end comprising at least one stiffener.

In some embodiments, an underfill compound and at least one electronic component is disposed on the transparent conductive film, the underfill compound being interposed between the transparent conductive film and the at least one electronic component. In some embodiments, an underfill compound, silver ink, and at least one electronic component are disposed on the transparent conductive film, the underfill compound being interposed between the silver ink and the electronic component. In some embodiments, carbon ink and silver ink is disposed on the tail portion, the silver ink being adapted to connect with at least one electronic component. In some embodiments, at least one electronic component is disposed on the tail portion and a conformal overcoat disposed on the at least one electronic component.

At least another embodiment provides a method of bonding at least one electronic component to a transparent conductive film, the transparent conductive film disposed onto a polymer substrate exhibiting a heat deflection temperature at which the polymer substrate becomes substantially deformable, the transparent conductive film comprising a body portion, a tail portion integrally formed with the body portion, and a plurality of conductive structures embedded within the body portion and the tail portion is disclosed. The method comprises applying an electronic assembly compound to either or both of the transparent conductive film or the at least one electronic component, and subjecting an electronic assembly compound, at least some of which is disposed between the transparent conductive film and the at least one electronic component, to a bonding temperature less than the heat deflection temperature of the polymer substrate, where the bonding temperature is less than about 185 degrees Celsius.

In some embodiments, the bonding temperature is less than about 180 degrees Celsius. In some embodiments, the bonding temperature is between about 135 degrees Celsius and about 155 degrees Celsius. In some embodiments, the bonding temperature is between about 140 degrees Celsius and about 150 degrees Celsius. In some embodiments, the bonding temperature is less than about 150 degrees Celsius. In some embodiments, the bonding temperature is less than about 140 degrees Celsius. In some embodiments, the electronic assembly compound comprises a silver epoxy. In some embodiments, the polymer compound comprises polyethylene terephthalate. In some embodiments, the plurality of conductive structures comprises silver nanowires.

In some embodiments, the method further comprises applying a silver ink onto the transparent conductive film, wherein the silver ink is interposed between the transparent conductive film and the electronic assembly compound. In some embodiments, the method further comprises applying a silver ink and a carbon ink onto the transparent conductive film, wherein the silver ink is disposed on the transparent conductive film and the carbon ink is interposed between the silver ink and the electronic assembly compound. In some embodiments, the method further comprises patterning a region of the transparent conductive film to form a patterned region exhibiting a first conductivity and an unpatterned region exhibiting a second conductivity, the first conductivity being less than the second conductivity.

In some embodiments, the method further comprises applying a dielectric compound that is curable by ultra violet radiation on the tail portion. In some embodiments, the method further comprises applying at least one electronic component on the electronic assembly compound. In some embodiments, the method further comprises applying an optical clear adhesive on the transparent conductive film. In some embodiments, the method further comprises applying an optical clear adhesive on the transparent conductive film and a cover lens on the optical clear adhesive. In some embodiments, the method further comprises applying a stiffener to the tail portion. In some embodiments, the method further comprises applying an underfill compound and at least one electronic component on the transparent conductive film, the underfill compound being interposed between the at least one electronic component and the transparent conductive film.

### DESCRIPTION OF FIGURES

FIG. 1A shows a side view of a touch panel module having a touch panel sensor comprising a TCF and FPC.

FIG. 1B shows a top view of the touch panel module of FIG. 1A.

FIG. 2 shows a top view of a touch panel module having a touch panel sensor comprising a TCF having integrally formed body portion and tail portion.

FIG. 3 shows a touch panel having electronic components assembled onto a TCF having a tail portion integrally formed with a body portion.

### DESCRIPTION

All publications, patents, and patent documents referred to in this document are incorporated by reference herein in their entirety, as though individually incorporated by reference.

U.S. Provisional Application No. 62/041,335, filed Aug. 25, 2014, entitled “TOUCH PANELS,” is hereby incorporated by reference in its entirety.

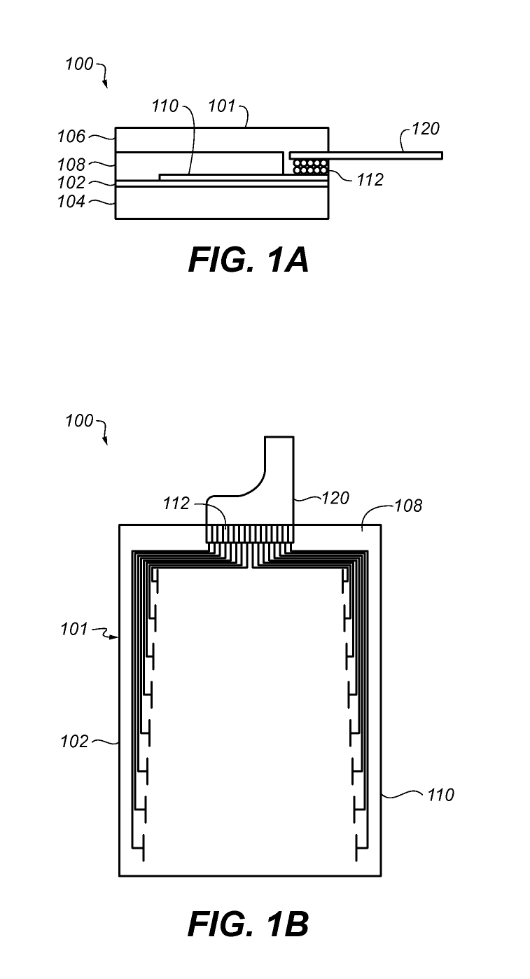

Touch panel modules may have a variety of configurations that may be produced using various fabrication methods. As shown in the side view of FIG. 1A and top view of FIG. 1B, a basic construction of a touch panel module 100 includes a touch panel sensor, a printed circuit board (PCB) (not shown), and a flexible printed circuit (FPC) 120 providing connections between the touch panel sensor 101 and the PCB (not shown). At least one connector (e.g. low insertion force (LIF), zero insertion force (ZIF), etc.) may be soldered to the PCB using either surface mount or through hole techniques. Contacts may be provided on the top side, bottom side, or both the top and bottom sides of a connector. The FPC 120 may be inserted into a connector on the PCB (not shown).

The touch panel sensor 101 may comprise a transparent conductive film (TCF) 102 disposed on a substrate 104, a cover lens 106, and an optically clear adhesive (OCA) 108 interposed between the cover lens 106 and the TCF 102. The TCF 102 may comprise conductive structures embedded within a matrix. A conductive paste 110 may be disposed on the TCF 102. The FPC 120 may be a separate component that is bonded to the conductive paste 110 on the TCF 102 using an anisotropic conductive film (ACF) 112. The OCA 108 may be disposed onto a portion of the TCF 102, such that a portion of the conductive paste 110 is not covered by the OCA 108 and may provide access to bonding with the FPC 120 via ACF 112.

To further manufacturing cost reductions and efficiency, one approach may be simplifying the design of the touch panels by removing unnecessary materials, components, and assembly time. One potential area of exploration is removal of the FPC and ACF. FPC is a platform for supporting electronic components, such as, for example active components or passive components. Active components are capable of introducing net energy into a circuit while passive components are not. An example of an active component is an integrated circuit (IC), also known as a touch panel controller, for controlling the touch panel sensor. An example of passive components includes resistors and capacitors. Such active and passive components may be directly placed onto the surface of the FPC, also known as surface-mount technology (SMT). By placing the active and passive components onto the FPC, the number of pins needed on the connector mounted on the PCB may be reduced.

As an approach to eliminating the FPC and ACF, a tail portion may be integrally formed with the transparent conductive film. The electronic components that are normally supported by the FPC may be attached to the tail portion. Conventional attachment techniques generally require temperatures in excess of 180 degrees Celsius (e.g. between about 185 degrees Celsius and about 235 degrees Celsius), which may cause degradation of the structural integrity of the substrate upon which the transparent conductive film is disposed. The substrate generally comprises a material of lower temperature resistance, such as for example, a thermoplastic material (e.g. polyethylene terephthalate (PET)). A material of lower temperature resistance (e.g. PET) is relatively less expensive and more readily available that a material of higher temperature resistance while being relatively strong, durable, impact-resistant, and well-suited as a substrate. Applicants have discovered materials and methods for attaching electronic components on a tail portion integrally formed with the TCF that is disposed on a substrate comprising thermoplastic material of lower temperature resistance.

### Transparent Conductive Film (TCF)

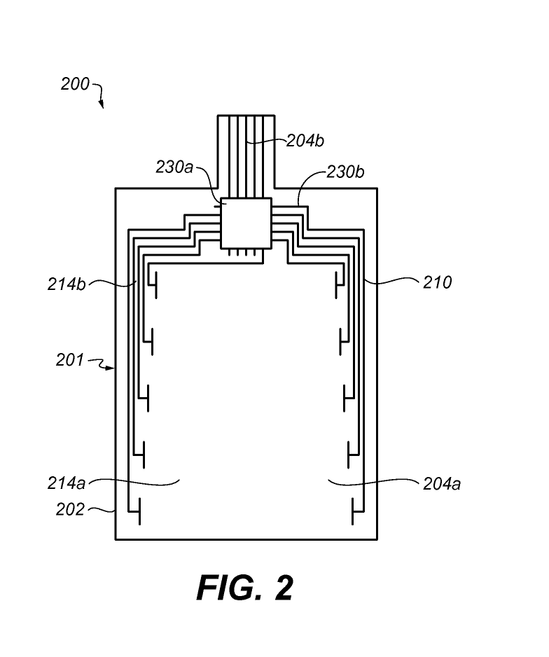

FIG. 2 shows a top view of a touch panel module 200 having a touch panel sensor 201 comprising a TCF 202 having integrally formed body portion 204a and tail portion 204b. The TCF 202 comprises a body portion 204a and a tail portion 204b that extends from the body portion 204a. At the junction where the body portion 204a and the tail portion 204b meet, the tail portion 204b has a smaller dimension (e.g. width of tail portion) than the body portion 204a (e.g. width of body portion), thus resembling the shape of a tail. It should be noted that the tail portion 204b could have alternative shapes and structures.

In an exemplary embodiment, the tail portion 204b is integrally formed with the body portion 204a. In this application, a first portion being “integrally formed with” the second portion may have any of the following definitions: 1) the first portion is continuous with the second portion (e.g. formed as an unbroken whole, without interruption, or in a smooth manner), or 2) the first portion and the second portion as a unit are formed with a common material and the connection between the first portion and the second portion has no mechanical joints.

The tail portion 204b and the body portion 204a may be formed in a single step and/or simultaneously with each other. Known coating or cutting methods may be used to integrally form the tail portion 204b and the body portion 204a. Some of these methods may involve the use of a mold with a pre-formed image to serve as a guide for producing the TCF with integral body portion 204a and tail portion 204b. A coating material may be disposed within the mold to form the TCF with integral body portion 204a and tail portion 204b. The mold may have sharp edges for cutting a film into a one-piece shape that defines a body portion 204a and a tail portion 204b. A laser may be used to separate or cut a TCF 202 with integral body portion 204a and tail portion 204b from a larger sheet of TCF 202.

The TCF 202 comprises a plurality of conductive structures, such as, for example, metal nanowires, metal mesh, or indium tin oxide. In exemplary embodiments, the TCF 202 comprises conductive structures, such as, for example, silver nanowires embedded into a polymer matrix. The polymer matrix may comprise a cellulose ester polymer, such as, for example, a cellulose acetate polymer, such as, for example, a cellulose acetate butyrate polymer (CAB). A conductive paste 210 may be disposed on the TCF 202.

### Tail Portion

In an exemplary embodiment as shown in FIG. 2, the tail portion replaces the separate component FPC and the ACF that is used to bond the FPC with the TCF. Since the FPC was a platform for the attachment of electronic components, the tail portion should be capable of supporting the electronic components, and one way of characterizing this capability is stiffness. The tail portion should have a sufficient stiffness that would support the weight of the electronic components. In this application, stiffness is the rigidity of an object, that is, the extent to which an object resists deformation in response to an applied force.

The tail portion may be supplemented with at least one stiffener that increases the rigidity of the tail portion. In some embodiments, the stiffener may be a material that is disposed on the tail portion. For example, the stiffener may be laminated to the tail portion. In some embodiments, the stiffener may be a composition added to the tail portion during the coating process. In some embodiments, the stiffener may be applied in such a manner so as to increase the thickness of the tail portion so the tail portion is compatible for connection with commercial connectors. The stiffener may provide strain relief. In this application, “strain” is a measure of deformation representing the displacement between particles in a body relative to a reference length. Strain relief may reduce flexibility, which improves ease and reliability of connection between the tail portion and the PCB, and reduce bending curvature due to the weight of the electronic components or force caused when connecting with the PCB. The stiffener may also provide greater flatness or stability for mechanical manipulation during assembly or connection. A variety of types of materials can be used as a stiffener, such as, for example, the polymers polyethylene terephthalate (PET), polyimide, polystyrene, polyvinylchloride (PVC), or combinations thereof.

The stiffener may be disposed on at least a part of the tail portion. In some embodiments, the stiffener may be disposed on an entire surface of the tail portion. In some embodiments, the stiffener may be disposed on part of the surface of the tail portion. The stiffener may be disposed on the end part of the tail portion for improved connection with the PCB. In this application, the end part of the tail portion is further away from the junction at which the body portion and tail portion meet. The stiffener may be disposed on any part of the tail portion upon which the electronic components are supported. The stiffener may be disposed on either of the opposing surfaces of the tail portion—a first surface upon which the electronic components are disposed or a second surface opposite the first surface. In some embodiments, the stiffener may be one or more adhesives. The adhesive may serve additional purposes, such as for example, attaching electronic components to the transparent conductive film. Non-limiting examples of adhesives include acrylics, epoxies, and polymers curable by ultraviolet radiation (i.e. UV curable polymers).

One or more stiffeners may be disposed on the tail portion. Where at least two stiffeners are used, the stiffeners may be disposed on different parts or regions of the tail portion. For example, the first stiffener may be disposed on a first surface upon which the electronic components are disposed at the end part of the tail portion, and the second stiffener may be disposed on a second surface directly underneath the electronic components.

### Electronic Components

In the typical touch panel construction as shown in FIGS. 1A and 1B, electronic components (not shown) are bonded to the flexible printed circuit 120, which is a separate part that is attached to the touch panel sensor 101. In the exemplary embodiment as shown in FIG. 2, electronic components 230a, 230b . . . may be disposed near or on the tail portion 204b that is integral with the body portion 204a of the transparent conductive film 202. In some embodiments, the electronic components are disposed on the periphery 214b of the body portion 204a outside the sensing region 214a of the body portion 204a. In this application, “sensing region” is intended to broadly encompass any space above, around, in, and/or near the touch panel where an object (e.g. finger) may affect capacitance that may be detected by associated control circuitry to infer the position of the object. For example, the sensing region 214a of the body portion 204a may be an area within the conductive compound that is disposed on the periphery 214b of the sensing region 214a. In some embodiments, the electronic components are disposed at the junction between where the tail portion 204b and the body portion 204a meet.

To bond electronic components to the exemplary transparent conductive film comprising a tail portion integral with a body portion, an electronic assembly compound (e.g. solder compound) may be used. Typical solder compounds (e.g. lead or lead-free solders) may have a higher bonding temperature (i.e. temperature at which the solder compound forms a bond between the electronic component and the transparent conductive film) than the heat deflection temperature (i.e. temperature at which a polymer or plastic deforms under a specified load) of the substrate that causes substantial deformation of the substrate. In some cases, bonding between the electronic compound and the transparent conductive film by the solder compound may occur when the solder compound changes from liquid to solid state. In cases where the solder compound comprises a polymer, bonding may occur through a curing process where the polymer toughens or hardens by cross-linking of polymer chains. The heat deflection temperature may be determined by the test procedure outlined in ASTM D648.

In this application, “a heat deflection temperature at which a polymer substrate becomes substantially deformable” is characterized by the substrate's substantial loss in dimensional stability or substantial change in size or shape from an applied force or change in temperature, such as for example, appearance of visible defects, deviation of optical properties and electrical conductivity of at least 10%, or relative displacement of a region of the substrate of at least 10% (e.g. 10% deviation in flatness or bending of 10%) when compared to its position prior to deformation. As an example, lead or lead-free solders require a bonding temperature from about 185 to about 235 degrees Celsius, which causes substantial deformation of substrates comprising materials such as PET, which is considered to be substantially deformable at temperatures above 180 degrees Celsius.

While one solution may be to use a substrate material that has a higher heat deflection temperature than the bonding temperature of an electronic assembly compound, such substrate materials tend to be more costly. A thermoplastic material having lesser resistance to deformation at typical electronic assembly compound bonding temperatures, such as PET, has shown to be a suitable substrate material for a transparent conductive film comprising conductive structures, such as silver nanowires. Such substrate materials have proven to yield a touch panel sensor exhibiting suitable optical and electrical conductivity properties.

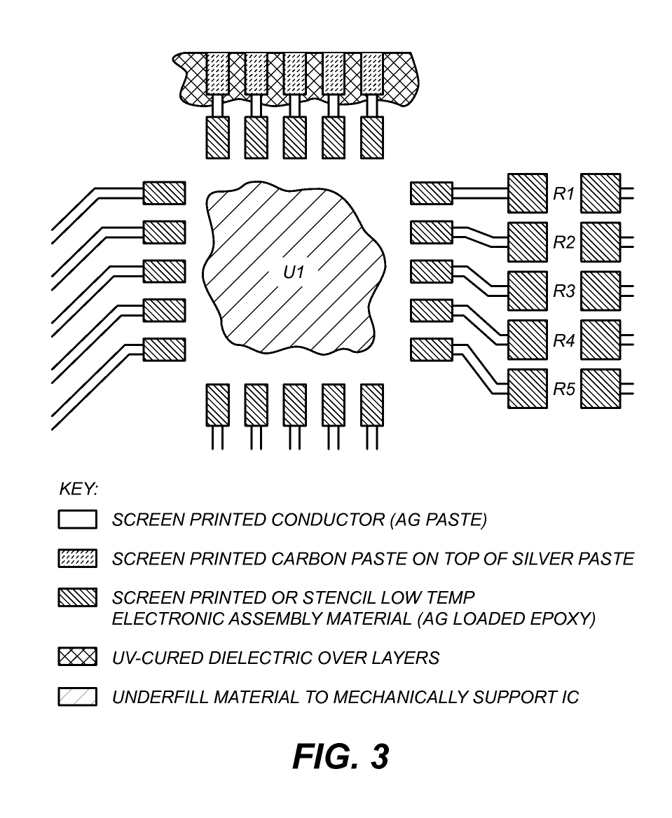

One approach to maintaining the use of substrates having a heat deflection temperature less than the bonding temperature of typical electronic assembly compounds is developing a method of using alternative electronic assembly compounds that have a bonding temperature lower than the heat deflection temperature of the substrates. FIG. 3 shows an exemplary embodiment of a touch panel having electronic components assembled onto a TCF having a tail portion integrally formed with a body portion.

The touch panel as shown in FIG. 3 may be formed by a method as described below. The steps may be performed in sequential or simultaneous (combined) steps or in a different order than presented below. A TCF having integral body portion and tail portion may be subjected to preparations prior to assembly of electronic components (e.g. cutting the TCF into a shape that includes an integral body and tail portion, removal of the liner that protects the TCF, annealing, etc.).

In an exemplary embodiment, one or more conductive compounds are applied to the TCF. The conductive compound may be a metallic compound, such as, for example, silver ink or silver paste. The conductive compound may be applied through various methods, such as, for example, screen printing or stencil printing. One or more non-conductive compounds may be disposed on the conductive compound near or at the region where the tail portion inserts into or makes contact with a connector (e.g. ZIF or LIF). The non-conductive compound may, for example, be a carbon ink or a carbon paste.

Certain regions of the TCF may be patterned to render those regions less conductive. Patterning may be accomplished through various methods, such as laser patterning or chemical etching (e.g. screen printed mask, screen printed etching, or photolithography). For example, parts of the sensing region of the TCF and areas between the overlapped conductive compound and non-conductive compound may be patterned. In some embodiments, the overlapped conductive compound and non-conductive compound may be ablated (not shown in FIG. 3). A UV curable dielectric layer may be disposed on the tail portion in areas that will not be used to bond with electronic components or inserted into a connector.

An electronic assembly compound or a solder compound may be disposed on the conductive compound for a sufficient thickness (e.g. at least 25 μm or at least 71 mil) to achieve a reliable bond between the TCF and the electronic components. The electronic assembly material or solder compound may be a compound that exhibits a lower bonding temperature than the heat deflection temperature of the substrate material. In some embodiments, the electronic assembly compound (e.g. solder compound) comprise an epoxy, such as, for example, 1-part or 2-part silver epoxy, and the substrate comprises a thermoplastic, such as, for example, PET. 1-part or 2-part silver epoxies may have bonding temperatures of between about 140 and about 150 degrees Celsius (or between about 135 degrees Celsius and about 155 degrees Celsius). PET may substantially deform at a heat deflection temperature above 150 degrees Celsius.

In some embodiments, it is useful to refer to the curing temperature range of an electronic assembly compound. For the purposes of this application, the term “curing temperature range” shall refer to the range of temperatures in which bonding can occur in less than about 15 minutes. For example, some 1-part or 2-part silver epoxies have curing temperature ranges from about 135 degrees Celsius to about 155 degrees Celsius. It is useful to use electronic assembly compounds where at least a portion of the curing temperature range is below the heat deflection temperature of the substrate. In such embodiments, the melting temperature of the electronic assembly compound is less than the lower bound of the curing temperature range.

An underfill compound may be dispensed in the center of the mounting area for the touch panel controller integrated circuit (IC). The underfill compound is used to fill in gaps that might be between the IC and TCF, reinforce the mechanical connection between the IC and TCF, provide a heat bridge, ensure that solder joints are not stressed due to differential heating, and distribute inconsistent thermal expansion between the IC and TCF to prevent stress concentration in solder joints and premature failure. The underfill compound may be deposited manually using a syringe or in an automated fashion using, for example, ink-jet or micro-dispense printing technologies. The electronic components (e.g. IC) may be loaded into an SMT pick-and-place machine and placed onto the TCF. The TCF is then typically placed into a reflow oven set between about 140 and about 150 degrees Celsius for about 5 to 10 minutes, or at other temperatures and times suitable for curing electronic assembly compounds that may be present.

An OCA may be cut to provide openings to expose the electronic components disposed at the end of the tail portion through the OCA when disposed onto the TCF. The OCA may be attached to the TCF through various means, such as lamination, exposure to a carbon dioxide laser, and autoclaving. A cover lens may be attached to the touch panel sensor through various means, such as lamination, and autoclaved.

A stiffener may be disposed onto the end of the tail portion to increase the thickness for compatibility with PCB connectors. In some embodiments, a conformal coating or dielectric compound may be disposed onto the surface mounted components and cured. In such cases, this step may be performed prior to attaching the OCA or cover lens to the TCF or else performed when the UV curable dielectric layer is disposed on the tail portion in areas not inserted into a connector or used to bond with electronic components. The method of attaching components may be performed on a sheet of TCF for creating multiple touch panel sensors and later separated into separate sensors or individual pre-cut sheets of TCF. The method may be performed simultaneously for creating multiple touch panel sensors.

### Exemplary Embodiments

U.S. Provisional Application No. 62/041,335, filed Aug. 25, 2014, entitled “TOUCH PANELS,” which is hereby incorporated by reference in its entirety, disclosed the following 58 non-limiting exemplary embodiments:

A. A touch panel comprising:

a polymer substrate exhibiting substantial deflection at a heat deflection temperature,

a transparent conductive film disposed on the polymer substrate, the transparent conductive film comprising a body portion, a tail portion integrally formed with the body portion, and a plurality of conductive structures at least some of which are embedded within the body portion and the tail portion, and

an electronic assembly compound disposed on the transparent conductive film for bonding with at least one electronic component, the at least one electronic component being bonded with the transparent conductive film at a bonding temperature less than the heat deflection temperature of the polymer substrate, wherein the bonding temperature is less than about 185 degrees Celsius.

B. The touch panel according to embodiment A, wherein the body portion comprises a first composition, and the tail portion comprises a second composition, the first composition and the second composition being the same.
C. The touch panel according to either of embodiments A or B, wherein the bonding temperature is less than about 180 degrees Celsius.
D. The touch panel according to any of embodiments A-C, wherein the bonding temperature is between about 135 degrees Celsius and about 155 degrees Celsius.
E. The touch panel according to any of embodiments A-D, wherein the bonding temperature is between about 140 degrees Celsius and about 150 degrees Celsius.
F. The touch panel according to any of embodiments A-E, wherein the bonding temperature is less than about 150 degrees Celsius.
G. The touch panel according to any of embodiments A-F, wherein the bonding temperature is less than about 140 degrees Celsius.
H. The touch panel according to any of embodiments A-G, wherein the electronic assembly compound comprises a silver epoxy.
J. The touch panel according to any of embodiments A-H, wherein the polymer substrate comprises polyethylene terephthalate.
K. The touch panel according to any of embodiments A-J, wherein the plurality of conductive structures comprises silver nanowires.
L. The touch panel according to any of embodiments A-K, further comprising a silver ink disposed onto the transparent conductive film, wherein the silver ink is interposed between the transparent conductive film and the electronic assembly compound.
M. The touch panel according to any of embodiments A-L, further comprising a silver ink and a carbon ink disposed onto the transparent conductive film, wherein the silver ink is interposed between the transparent conductive film and the carbon ink and the carbon ink is interposed between the silver ink and the electronic assembly compound.
N. The touch panel according to any of embodiments A-M, the transparent conductive film comprises a patterned region exhibiting a first conductivity and an unpatterned region exhibiting a second conductivity, the first conductivity being less than the second conductivity.
P. The touch panel according to any of embodiments A-N, further comprising a dielectric compound curable by ultraviolet radiation disposed on the tail portion.
Q. The touch panel according to any of embodiments A-P, further comprising at least one electronic component disposed on the electronic assembly compound.
R. The touch panel according to any of embodiments A-P, further comprising an optical clear adhesive disposed on the transparent conductive film.
S. The touch panel according to any of embodiments A-R, further comprising a cover lens disposed on the optical clear adhesive.
T. The touch panel according to any of embodiments A-S, wherein the electronic assembly compound is disposed on the tail portion.
U. The touch panel according to any of embodiments A-T, wherein the electronic assembly compound is disposed on the tail portion, the at least one electronic component is disposed on the electronic assembly compound, and the at least one stiffener is disposed under the at least one electronic component.
V. The touch panel according to any of embodiments A-U, wherein the tail portion comprises a first end connected with the body portion and a second end configured for connection with a connector, the second end comprising at least one stiffener.
W. The touch panel according to any of embodiments A-V, further comprising an underfill compound and at least one electronic component disposed on the transparent conductive film, the underfill compound being interposed between the transparent conductive film and the at least one electronic component.
X. The touch panel according to any of embodiments A-W, further comprising an underfill compound, silver ink, and at least one electronic component disposed on the transparent conductive film, the underfill compound being interposed between the silver ink and the electronic component.
Y. The touch panel according to any of embodiments A-X, further comprising carbon ink and silver ink disposed on the tail portion, the silver ink being adapted to connect with at least one electronic component.
Z. The touch panel according to any of embodiments A-Y, further comprising at least one electronic component disposed on the tail portion and a conformal overcoat disposed on the at least one electronic component.
AA. A method of bonding at least one electronic component to a transparent conductive film, the transparent conductive film disposed onto a polymer substrate having a heat deflection temperature, the transparent conductive film comprising a body portion, a tail portion integrally formed with the body portion, and a plurality of conductive structures at least some of which are embedded within the body portion and the tail portion, the method comprising:

subjecting an electronic assembly compound interposed between the transparent conductive film and at least one electronic component to a bonding temperature less than the heat deflection temperature of the polymer substrate, wherein the bonding temperature is less than about 185 degrees Celsius.

AB. The method according to embodiment AA, wherein the bonding temperature is less than about 180 degrees Celsius.
AC. The method according to either of embodiments AA or AB, wherein the bonding temperature is between about 135 degrees Celsius and about 155 degrees Celsius.
AD. The method according to any of embodiments AA-AC, wherein the bonding temperature is between about 140 degrees Celsius and about 150 degrees Celsius.
AE. The method according to any of embodiments AA-AD, wherein the bonding temperature is less than about 150 degrees Celsius.
AF. The method according to any of embodiments AA-AE, wherein the bonding temperature is less than about 140 degrees Celsius.
AG. The method according to any of embodiments AA-AF, wherein the electronic assembly compound comprises a silver epoxy.
AH. The method according to any of embodiments AA-AG, wherein the polymer compound comprises polyethylene terephthalate.
AJ. The method according to any of embodiments AA-AH, wherein the plurality of conductive structures comprises silver nanowires.
AK. The method according to any of embodiments AA-AJ, further comprising applying a silver ink onto the transparent conductive film, wherein the silver ink is interposed between the transparent conductive film and the electronic assembly compound.
AL. The method according to any of embodiments AA-AK, further comprising applying a silver ink and a carbon ink onto the transparent conductive film, wherein the silver ink is disposed on the transparent conductive film and the carbon ink is interposed between the silver ink and the electronic assembly compound.
AM. The method according to any of embodiments AA-AL, further comprising patterning a region of the transparent conductive film to form a patterned region exhibiting a first conductivity and an unpatterned region exhibiting a second conductivity, the first conductivity being less than the second conductivity.
AN. The method according to any of embodiments AA-AM, further comprising applying a dielectric compound that is curable by ultra violet radiation on the tail portion.
AP. The method according to any of embodiments AA-AN, further comprising applying at least one electronic component on the electronic assembly compound.
AQ. The method according to any of embodiments AA-AP, further comprising applying an optical clear adhesive on the transparent conductive film.
AR. The method according to any of embodiments AA-AQ, further comprising applying an optical clear adhesive on the transparent conductive film and a cover lens on the optical clear adhesive.
AS. The method according to any of embodiments AA-AR, further comprising applying a stiffener to the tail portion.
AT. The method according to any of embodiments AA-AS, further comprising applying an underfill compound and at least one electronic component on the transparent conductive film, the underfill compound being interposed between the at least one electronic component and the transparent conductive film.
AU. The touch panel according to any of embodiments A-Z, wherein the transparent conductive film is a one-piece transparent conductive film.
AV. The method according to any of embodiments AA-AT, wherein the transparent conductive film is a one-piece transparent conductive film.
AW. A touch panel comprising:

a polymer substrate exhibiting a heat deflection temperature according to ASTM D648,

a transparent conductive film disposed on the polymer substrate, the transparent conductive film comprising a body portion, a tail portion comprising a plurality of electrical connectors, the tail portion being integrally formed with the body portion, and a plurality of conductive structures at least some of which are embedded in the body portion and tail portion,

an electronic assembly compound disposed on the transparent conductive film, the electronic assembly compound exhibiting a melting point and a curing temperature range, and

at least one electronic component bonded to the transparent film by the electronic assembly compound,

wherein at least a portion of the curing temperature range is less than the heat deflection temperature of the polymer substrate, and

further wherein at least a portion of the curing temperature range is less than 185° C.

AX. The touch panel according to embodiment AW, wherein the transparent conductive film is a one-piece transparent conductive film.
AY. The touch panel according to either of embodiments AW-AX, wherein the curing temperature range is less than 185° C.
AZ. The touch panel according to any of embodiments AW-AY, wherein at least a portion of the curing temperature range is less than 180° C.
BA. The touch panel according to any of embodiments AW-AZ, wherein the curing temperature range is less than 180° C.
BB. The touch panel according to any of embodiments AW-BA, wherein the curing temperature range is between about 135° C. and about 155° C.
BC. The touch panel according to any of embodiments AW-BB, wherein the curing temperature range is between about 140° C. and about 150° C.
BD. The touch panel according to any of embodiments AW-BC, wherein at least a portion of the curing temperature range is less than about 150° C.
BE. The touch panel according to any of embodiments AW-BD, wherein the curing temperature range is less than 150° C.
BF. The touch panel according to any of embodiments AW-BB and BD-BE, wherein at least a portion of the curing temperature range is less than about 140° C.
BG. The touch panel according to any of embodiments AW-BB and BD-BF, wherein the curing temperature range is less than about 140° C.
BH. The touch panel according to any of embodiments AW-BG, wherein the electronic assembly compound comprises at least one silver epoxy.
BJ. The touch panel according to any of embodiments AW-BH, wherein the conductive structures comprise silver nanowires.
BK. The touch panel according to any of embodiments AW-BJ, wherein the polymer substrate comprises polyethylene terephthalate.

### EXAMPLES

### Example 1

### Prophetic

A TCF is cut into a size and shape to accommodate the body portion and the tail portion. The liner is removed from the TCF, and the TCF is annealed at 150 degrees Celsius for 30 minutes. Silver ink is screen printed onto the TCF and dried and cured at a temperature of about 130 to 150 degrees Celsius for about 10 to 30 minutes. Carbon ink is screen printed onto the silver ink near or at the area where the tail portion inserts into a PCB connector and dried and cured at a temperature of about 130 to 150 degrees Celsius for about 10 to 30 minutes. The TCF is patterned by laser to render desired areas less conductive in the sensing region that detects contact with an object and between inks. A UV-curable dielectric cover layer compound is screen printed onto the tail portion in areas that will not be inserted into a connector or used to bond with components and dried and cured. A 2-part silver epoxy is prepared and stencil printed onto the silver ink for a thickness of greater than 25 μm or 71 mil. An underfill compound is dispensed in the area where the integrated circuit will be mounted. Electronic components are loaded into an SMT pick-and-place machine. Electronic components are disposed onto the TCF. The TCF is placed in a reflow oven set a temperature between about 140 to about 150 degrees Celsius for about 5 to 10 minutes to cure the 2-party silver epoxy. Openings are cut into the OCA so the OCA will not cover the components or the end of the tail portion. OCA is laminated to the TCF, singulated with a carbon dioxide laser, and autoclaved. A cover lens is laminated to the TCF and autoclaved. A coating is disposed onto the SMT components and cured. A stiffener is laminated to the end of the tail portion for a total thickness that is compatible with standard ZIF or LIF connectors. FIG. 3 shows an embodiment of a touch panel as created by the method as described in Example 1.

The invention has been described in detail with reference to specific embodiments, but it will be understood that variations and modifications can be effected within the spirit and scope of the invention. The presently disclosed embodiments are therefore considered in all respects to be illustrative and not restrictive. The scope of the invention is indicated by the attached claims, and all changes that come within the meaning and range of equivalents thereof are intended to be embraced therein.

What is claimed:

1. A touch panel comprising:
a polymer substrate exhibiting a heat deflection temperature at which the polymer substrate becomes substantially deformable,
a transparent conductive film disposed on the polymer substrate, the transparent conductive film comprising a body portion, a tail portion integrally formed with the body portion, and a plurality of conductive structures at least some of which are embedded within the body portion and tail portion,
an electronic assembly compound disposed between the transparent conductive film and at least one electronic component, the electronic assembly compound exhibiting a curing temperature range that is less than 185° C., at least a portion of the curing temperature range being colder than the heat deflection temperature,
wherein the at least one electronic component is bonded to the transparent conductive film by the electronic assembly compound.

2. The touch panel according to claim 1, wherein the body portion consists of a first composition and the tail portion consists of a second composition, the first composition and second composition being identical.

3. The touch panel according to claim 1, wherein the polymer substrate comprises polyethylene terephthalate, the plurality of conductive structures comprises silver nanowires, and the electronic assembly compound comprises silver epoxy.

4. The touch panel according to claim 1, further comprising a silver ink, at least some of which is disposed between the transparent conductive film and the electronic assembly.

5. The touch panel according to claim 1, further comprising a carbon ink, at least some of which is disposed between the silver ink and the electronic assembly compound.

6. The touch panel according to claim 1, wherein the entirety of the curing temperature range is colder than the heat deflection temperature.

7. The touch panel according to claim 1, wherein the curing temperature range is less than 180° C.

8. The touch panel according to claim 1, wherein the curing temperature range is between about 135° C. and about 155° C.

9. The touch panel according to claim 1, wherein the curing temperature range is between about 140° C. and about 150° C.

10. The touch panel according to claim 1, wherein at least a portion of the curing temperature range is less than 140° C.

11. A method for bonding at least one electronic component to a transparent conductive film, the transparent conductive film being disposed on a polymer substrate exhibiting a heat deflection temperature at which the polymer substrate becomes substantially deformable, the transparent conductive film comprising a body portion, a tail portion integrally formed with the body portion, and a plurality of conductive structures at least some of which are embedded within the body portion and tail portion, the method comprising:
applying an electronic assembly compound to either or both of the transparent conductive film or the at least one electronic component.
subjecting the electronic assembly compound, at least some of which is disposed between the transparent conductive film and the at least one electronic component, to a bonding temperature that is less than the heat deflection temperature of the polymer substrate,
wherein the bonding temperature is less than about 185° C.

12. The method according to claim 11, wherein the body portion consists of a first composition and the tail portion consists of a second composition, the first composition and second composition being identical.

13. The method according to claim 11, wherein the polymer substrate comprises polyethylene terephthalate, the plurality of conductive structures comprises silver nanowires, and the electronic assembly compound comprises silver epoxy.

14. The method according to claim 11, further comprising applying a silver ink, wherein at least a portion of the silver ink is disposed between the transparent conductive film and the electronic assembly compound.

15. The method according to claim 14, further comprising applying a carbon ink, wherein at least a portion of the carbon ink is disposed between the silver ink and the electronic assembly compound.

16. The method according to claim 11, wherein the bonding temperature is less than about 180° C.

17. The method according to claim 11, wherein the bonding temperature is between about 135° C. and about 155° C.

18. The method according to claim 11, wherein the bonding temperature is between about 140° C. and about 150° C.

19. The method according to claim 11, wherein the bonding temperature is less than about 150° C.

20. The method according to claim 11, wherein the bonding temperature is less than about 140° C.
